(19) United States
(12) Patent Application Publication
(10) Pub. No.: US 2026/0123122 A1
(43) Pub. Date: Apr. 30, 2026

(54) OPTOELECTRONIC DEVICE

(71) Applicant: ams-OSRAM International GmbH, Regensburg (DE)

(72) Inventors: Erwin LANG, Regensburg (DE); Patrick HOERNER, Bamberg (DE); Michael JOBST, Wiesenfelden (DE); Daniel KRAUS, Regensburg (DE)

(21) Appl. No.: 18/859,128

(22) PCT Filed: Feb. 16, 2023
(86) PCT No.: PCT/EP2023/053930

§ 371 Date: Oct. 22, 2024

(30) Foreign Application Priority Data
Apr. 27, 2022 (DE) 10 2022 110 160.6

(51) Int. Cl. H10H 20/857; G06F 3/044; H01L 25/075

(52) U.S. Cl. CPC H10H 20/857; G06F 3/0443; H10W 90/00

(57) ABSTRACT

The invention relates to an optoelectronic device comprising a carrier with a front face and a rear face. First metal structures are arranged on the front face of the carrier. An optoelectronic semiconductor chip arranged on the front face of the carrier is electrically contacted via the first metal structures. The first metal structures are at least partially covered by a first dielectric. A second dielectric forms an outer surface of the optoelectronic device which is intended to be touched by a user. The second dielectric has a higher permittivity than the first dielectric. The carrier has second metal structures which are intended to detect a change in capacitance resulting from the user touching the optoelectronic device.

### CROSS-REFERENCE TO RELATED APPLICATIONS

This patent application is a national stage application filed under 35 U.S.C. 371 based on International Patent Application No. PCT/EP2023/053930, filed Feb. 16, 2023, which claims the priority of the German patent application DE 10 2022 110 160.6, filed Apr. 27, 2022, the disclosures of which are hereby incorporated by reference in their entireties.

### BACKGROUND

The present invention relates to an optoelectronic device.

Devices that combine an optoelectronic light source and a touch-sensitive operating element are known in the prior art. The construction from independent individual components imposes limits on miniaturization here.

### SUMMARY

One aspect of the present invention is to provide an optoelectronic device. This aspect is achieved by an optoelectronic device having the features of the independent claim. Various developments are specified in the dependent claims.

An optoelectronic device comprises a carrier comprising a front side and a rear side. First metallic structures are arranged on the front side of the carrier. An optoelectronic semiconductor chip arranged on the front side of the carrier is electrically contacted via the first metallic structures. The first metallic structures are at least partly covered by a first dielectric. A second dielectric forms an outer surface of the optoelectronic device that is provided for being touched by a user. The second dielectric comprises a higher permittivity than the first dielectric. The carrier comprises second metallic structures provided for detecting a change in a capacitance that results from a user touching the optoelectronic device.

This optoelectronic device thus combines an optoelectronic functionality and a touch-sensitive operating functionality (touch functionality). In this case, both functionalities are realized on the same carrier of the optoelectronic device, whereby the optoelectronic device may comprise compact external dimensions, in particular just a small thickness. Providing the first dielectric comprising a lower permittivity makes it possible to reduce disturbing influences on the second metallic structures of the touch-sensitive operating functionality that arise from the first metallic structures of the optoelectronic functionality, whereby a disturbance sensitivity of the operating functionality may be reduced. Providing the second dielectric comprising a higher permittivity makes it possible for the sensitivity and accuracy of the operating functionality to be high. The touch-sensitive operating functionality of this optoelectronic device may thus advantageously offer a high signal-to-noise ratio.

In one embodiment of the optoelectronic device, the first dielectric is covered by the second dielectric. This arrangement advantageously enables an effective separation of the functionalities of the optoelectronic device and a configuration of the operating functionality with high sensitivity. Moreover, the optoelectronic device may be produced simply and cost-effectively in this case.

In one embodiment of the optoelectronic device, the carrier is configured as a film, in particular as a monolayer film. This advantageously results in a compact construction of the optoelectronic device, in particular a small thickness. The configuration of the carrier as a film may also make it possible for the optoelectronic device to be configured in a mechanically flexible manner.

In one embodiment of the optoelectronic device, the second metallic structures are arranged on the front side of the carrier. As a result, both the optoelectronic functionality and the touch-sensitive operating functionality are configured on the front side of the carrier. As a result, the rear side of the carrier may serve for example for securing the optoelectronic device at an installation location.

In one embodiment of the optoelectronic device, the second metallic structures are arranged at least in portions on the first dielectric. Advantageously, a disturbing influence on the second metallic structures that arises from the first metallic structures may be particularly effectively reduced as a result. Moreover, the arrangement of the second metallic structures on the first dielectric may advantageously enable a crossover between the first metallic structures and the second metallic structures.

In one embodiment of the optoelectronic device, the second metallic structures are embedded directly in the second dielectric. This advantageously results in a simple and compact construction of the optoelectronic device. Moreover, the embedding of the second metallic structures in the second dielectric comprising a higher permittivity may achieve the effect that a user touching the optoelectronic device results in a clear and easily detectable change in the monitored capacitance.

In one embodiment of the optoelectronic device, the second metallic structures are arranged on the rear side of the carrier. This arrangement advantageously enables a particularly effective separation of the first metallic structures of the optoelectronic functionality and the second metallic structures of the touch-sensitive operating functionality. The arrangement of the second metallic structures on the rear side of the carrier may also support an operability of the optoelectronic device from the rear side of the carrier. Moreover, the arrangement of the second metallic structures on the rear side of the carrier may allow an even more compact embodiment of the optoelectronic device.

In one embodiment of the optoelectronic device, the second metallic structures arranged on the rear side of the carrier are covered by a third dielectric. In this case, the third dielectric comprises a higher permittivity than the first dielectric. The higher permittivity of the third dielectric may advantageously increase the sensitivity of the operating functionality of the optoelectronic device that is realized by the second metallic structures. The third dielectric may also enable an operability of the optoelectronic device from the rear side of the carrier.

In one embodiment of the optoelectronic device, a fourth dielectric is additionally arranged on the rear side of the carrier. In this case, the fourth dielectric is covered by the third dielectric. The third dielectric comprises a higher permittivity than the fourth dielectric. The fourth dielectric comprising a lower permittivity may advantageously contribute to reducing a disturbing influencing of the second metallic structures by the first metallic structures of the optoelectronic functionality.

In another embodiment of the optoelectronic device, the second metallic structures are covered by a fifth dielectric. In this case, the fifth dielectric comprises a lower permittivity than the second dielectric. The fifth dielectric comprising a lower permittivity may advantageously contribute to reducing a disturbing influencing of the touch-sensitive operating functionality—realized by the second metallic structures—by the first metallic structures of the optoelectronic functionality.

In one embodiment of the optoelectronic device, the outer surface provided for being touched by a user comprises at least one raised region and at least one recessed region. In this case, the recessed region is arranged over the second metallic structures in a direction perpendicular to the front side of the carrier. Advantageously, the distance between the second metallic structures and a point for touching by an operating user may be reduced by the recessed region, whereby the touch-sensitive operating functionality of the optoelectronic device may comprise an increased sensitivity.

In one embodiment of the optoelectronic device, the optoelectronic semiconductor chip is embedded in the first dielectric. A disturbing influencing of the second metallic structures by the optoelectronic semiconductor chip is advantageously particularly effectively reduced as a result. At the same time the first dielectric may advantageously serve for protection of the optoelectronic semiconductor chip.

In another embodiment of the optoelectronic device, the optoelectronic semiconductor chip is embedded directly in the second dielectric. This may advantageously make it possible to mount the optoelectronic semiconductor chip only after the first dielectric has been applied.

In one embodiment of the optoelectronic device, the second metallic structures comprise a first electrode. In this case, the optoelectronic device is configured to detect a change in a capacitance between the first electrode and a reference potential that results from a user touching the device. This advantageously makes it possible to reliably recognize that a user is touching the optoelectronic device.

In one embodiment of the optoelectronic device, the second metallic structures comprise a first electrode and a second electrode. In this case, the optoelectronic device is configured to detect a change in a capacitance between the first electrode and the second electrode that results from a user touching the device. This construction, too, advantageously makes it possible to reliably recognize that a user is touching the optoelectronic device.

In one embodiment of the optoelectronic device, the optoelectronic semiconductor chip is configured for emitting light. In this case, the first dielectric is substantially transparent to light emitted by the optoelectronic semiconductor chip. Advantageously, as a result, light emitted by the optoelectronic semiconductor chip is not shaded by the first dielectric.

In one embodiment of the optoelectronic device, the optoelectronic semiconductor chip is configured for emitting light. In this case, the second dielectric is substantially transparent to light emitted by the optoelectronic semiconductor chip. Advantageously, as a result, light emitted by the optoelectronic semiconductor chip is not shaded by the second dielectric.

### BRIEF DESCRIPTION OF THE DRAWINGS

The above-described properties, features and advantages of this invention and the way in which they are achieved will become clearer and more clearly understood in association with the following description of the exemplary embodiments which are explained in greater detail in association with the drawings, in which, in each case in a schematic illustration:

FIG. 1 shows a sectional side view of a first variant of an optoelectronic device;

FIG. 2 shows a first variant of a touch-sensitive operating functionality;

FIG. 3 shows a second variant of a touch-sensitive operating functionality;

FIG. 4 shows a sectional side view of a further variant of an optoelectronic device;

FIG. 5 shows a sectional side view of a further variant of an optoelectronic device;

FIG. 6 shows a sectional side view of a further variant of an optoelectronic device;

FIG. 7 shows a sectional side view of a further variant of an optoelectronic device;

FIG. 8 shows a sectional side view of a further variant of an optoelectronic device; and

FIG. 9 shows a sectional side view of a further variant of an optoelectronic device.

### DETAILED DESCRIPTION

FIG. 1 shows a schematic sectional side view of a part of an optoelectronic device 10. The optoelectronic device 10 may serve as a combined display and operating device. For this purpose, the optoelectronic device 10 comprises an optoelectronic functionality and a touch-sensitive operating functionality (touch functionality). The optoelectronic functionality comprises the possibility of emitting electromagnetic radiation, in particular visible light. The touch-sensitive operating functionality enables operation by a user of the optoelectronic device 10 by way of touching with a finger, for example.

The optoelectronic device 10 comprises a substantially flat shape comprising a front side 11 and a rear side 12 opposite the front side 11.

The optoelectronic device 10 comprises a carrier 100. The carrier 100 comprises a substantially flat and thin shape comprising a front side 101 and a rear side 102 opposite the front side 101. The carrier 100 may be configured for example as a film, in particular as a monolayer film. For example, the carrier 100 may be configured as a film composed of a plastics material, for example composed of PET.

First metallic structures 200 are arranged on the front side 101 of the carrier 100. The first metallic structures 200 form electrical contact pads and electrical conductor tracks.

Furthermore, an optoelectronic semiconductor chip 400 is arranged on the front side 101 of the carrier 100. The optoelectronic device 10 may also comprise a plurality of optoelectronic semiconductor chips 400. Two optoelectronic semiconductor chips 400 are illustrated by way of example in FIG. 1. The individual optoelectronic semiconductor chips 400 may be configured identically or differently. One of the optoelectronic semiconductor chips 400 is described by way of example below.

The optoelectronic semiconductor chip 400 is configured to emit electromagnetic radiation, for example visible light. The optoelectronic semiconductor chip 400 may be configured for example as a light-emitting diode chip (LED chip) or as a laser chip.

The optoelectronic semiconductor chip 400 comprises a first side 401 and a second side 402 opposite the first side 401. The second side 402 is oriented toward the front side 101 of the carrier 100.

The optoelectronic semiconductor chip 400 is electrically contacted via the first metallic structures 200. For this purpose, the optoelectronic semiconductor chip 400 comprises electrical contact pads on its second side 402, said electrical contact pads being electrically conductively connected to contact pads formed by the first metallic structures 200.

The optoelectronic semiconductor chip 400 may be configured as a surface emitting semiconductor chip. In this case, the optoelectronic semiconductor chip 400 may be configured for example to emit electromagnetic radiation at its first side 401. In this case, the optoelectronic semiconductor chip 400 may be configured as a flip-chip, for example. However, the optoelectronic semiconductor chip 400 may also be configured to emit electromagnetic radiation at its second side 402. In this case, the emission of light takes place through the carrier 100, which is expediently configured as transparent in this case. The optoelectronic semiconductor chip 400 may also be configured as a volume emitting semiconductor chip 400. In this case, the optoelectronic semiconductor chip 400 may emit electromagnetic radiation in all spatial directions. It is also possible for the optoelectronic device 10 to comprise a plurality of optoelectronic semiconductor chips 400, some of which emit at their first side 401 and some at their second side 402.

A first dielectric 510 is arranged on the front side 101 of the carrier 100, and at least partly covers the first metallic structures 200. In the example shown in FIG. 1, the first metallic structures 200 are completely covered by the first dielectric 510. Moreover, in the example shown in FIG. 1, the optoelectronic semiconductor chip 400 is embedded in the first dielectric 510. It is therefore expedient for the first dielectric 510 to be substantially transparent to light emitted by the optoelectronic semiconductor chip 400.

The first dielectric 510 is structured in a lateral direction, such that the first dielectric 510 does not cover the entire front side 101 of the carrier 100. This may have been achieved for example by subsequent structuring of a layer initially applied to the front side 101 of the carrier 100 in an areal fashion. Alternatively, the first dielectric 510 may have been applied directly in structured form, for example by way of a printing method.

The first dielectric 510 comprises a dielectric material comprising a low permittivity (dielectric constant). The first dielectric 510 may be configured for example as a low-k dielectric and may comprise for example a permittivity which is less than that of SiO₂, for example less than 3.9.

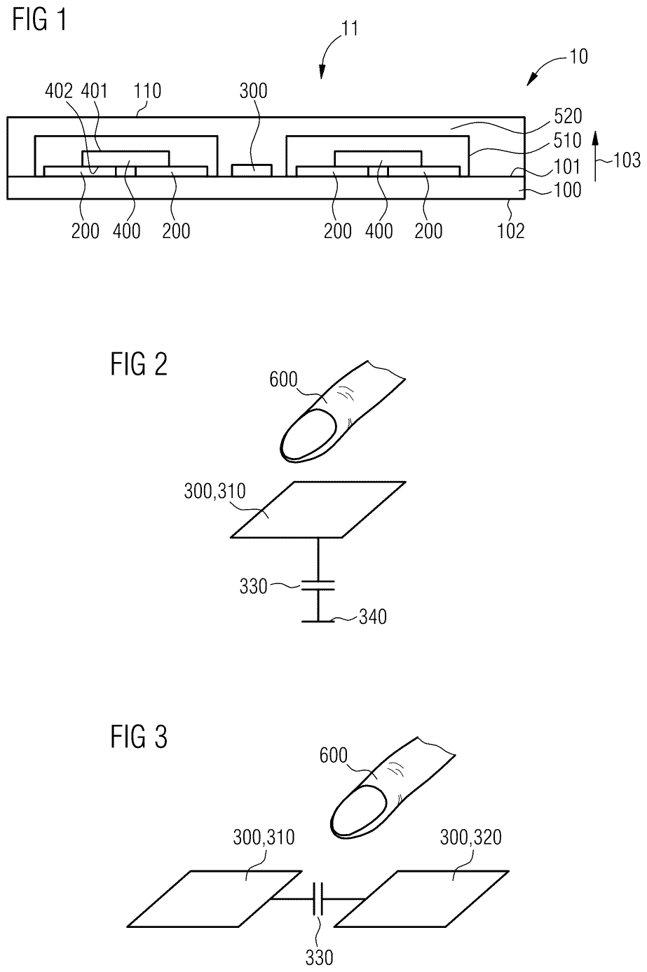

Second metallic structures 300 are arranged on the front side 101 of the carrier 100. The second metallic structures 300 form conductor tracks and one or more electrodes. The second metallic structures 300 serve to realize the touch-sensitive operating functionality of the optoelectronic device 10. This is explained below with reference to FIGS. 2 and 3.

FIG. 2 shows a schematic illustration of a portion of the second metallic structures 300 in accordance with a first variant of the touch-sensitive operating functionality. The illustrated portion of the second metallic structures 300 forms a first electrode 310. The first electrode 310 comprises an electrical capacitance 330 (inherent capacitance) with respect to a reference potential 340, which may be a ground potential, for example. If a body part, for example a finger, of a user 600 of the optoelectronic device 10 approaches the first electrode 310, then the value of the electrical capacitance 330 changes, which may be detected with the aid of an electrical circuit. It is thereby possible to detect the user 600 touching the optoelectronic device 10.

FIG. 3 shows a schematic illustration of an alternative design of the second metallic structures 300 in accordance with a second variant of the touch-sensitive operating functionality. In this variant, the second metallic structures 300 comprise a second electrode 320 besides the first electrode 310. There is an electrical capacitance 330 between the first electrode 310 and the second electrode 320. If a body part, for example a finger, of the user 600 of the optoelectronic device 10 approaches the first electrode 310 and the second electrode 320, then the capacitance 330 changes, which may be detected with the aid of an electrical circuit. In this way, too, it is possible to detect the user 600 touching the optoelectronic device 10.

The portions of the second metallic structures 300 that are provided for recognizing that the user 600 of the optoelectronic device 10 is touching the latter are arranged alongside the first metallic structures 200 and alongside the optoelectronic semiconductor chip 400 on the front side 101 of the carrier 100, as is shown in FIG. 1. If the optoelectronic device 10 comprises a plurality of optoelectronic semiconductor chips 400, then the portions of the second metallic structures 300 that are provided for detecting touch may be arranged between two adjacent optoelectronic semiconductor chips 400, for example. The second metallic structures 300 may also comprise a plurality of sets of electrodes for detecting touches, which in this case are arranged next to one another in a lateral direction on the front side 101 of the carrier 100 in order to be able to recognize touches by the user 600 at a plurality of lateral positions.

The second metallic structures 300 may have been formed for example jointly with the first metallic structures 200 on the front side 101 of the carrier 100.

FIG. 1 furthermore shows that the optoelectronic device 10 comprises a second dielectric 520. The second dielectric 520 is arranged on the front side 101 of the carrier 100 and covers both the first dielectric 510 and the second metallic structures 300. In this case, the second dielectric 520 forms an outer surface 110 provided for being touched by the user 600 on the front side 11 of the optoelectronic device 10.

The second dielectric 520 comprises a dielectric material, the permittivity of which is higher than that of the first dielectric 510. The second dielectric 520 may comprise for example a permittivity which is greater than that of SiO₂, for example greater than 3.9. It is expedient if the second dielectric 520 is substantially transparent to light emitted by the optoelectronic semiconductor chip 400.

In the case of the optoelectronic device 10, the region between the outer surface 110 provided for being touched by the user 600 and the second metallic structures 300 is filled with the second dielectric 520 comprising a high permittivity. What is achieved as a result is that an instance of the user 600 touching the outer surface 110 causes a distinct change in the capacitance 330 and may thus be reliably detected.

By virtue of the first metallic structures 200 and the optoelectronic semiconductor chip 400 being covered by the first dielectric 510 comprising a low permittivity in the case of the optoelectronic device 10, what is achieved is that the first metallic structures 200 and the optoelectronic semiconductor chip 400 have only a slight disturbing influence on the second metallic structures 300 and in particular the capacitance 330 monitored for recognizing touch by the user 600.

In the case of the variant of the optoelectronic device 10 shown in FIG. 1, the outer surface 110 formed by the second dielectric 520 and provided for being touched by the user 600 is configured as substantially planar and parallel to the front side 101 of the carrier 100. Therefore, in different lateral portions, the second dielectric 520 comprises a different thickness measured in a direction 103 perpendicular to the front side 101 of the carrier 100. In regions in which the second dielectric 520 covers the first dielectric 510, the second dielectric 520 comprises a smaller thickness in the perpendicular direction 103 than in regions over the second metallic structures 300. The second dielectric 520 may have been applied for example by a printing method, by a spraying method, by a casting method or by a molding method (mold method).

The touch-sensitive operating functionality of the optoelectronic device 10 need not require direct physical touching of the outer surface 110 by a body part of the user. The portions of the second metallic structures 300 that are provided for recognizing that the user 600 of the optoelectronic device 10 is touching the latter may be configured such that sufficient approaching toward the outer surface 110 by the user's body part is already detectable. In this sense, approaching toward the outer surface 110 by the user's body part in a manner sufficient for detection also constitutes touching. Consequently, touching the outer surface 110 does not require direct contact between a body part of the user and the outer surface 110.

The optoelectronic device 10 may comprise a cover (not illustrated in FIG. 1) on its front side 11, said cover being arranged over the outer surface 110 provided for being touched by the user 600. The cover may be configured as a transparent sheet, for example, and may comprise a glass or a plastic, for example. In this case, the outer surface 110 provided for being touched by the user 600 is touched indirectly by the cover being touched. In this case, the user's body part is caused to approach sufficiently close to the outer surface 110.

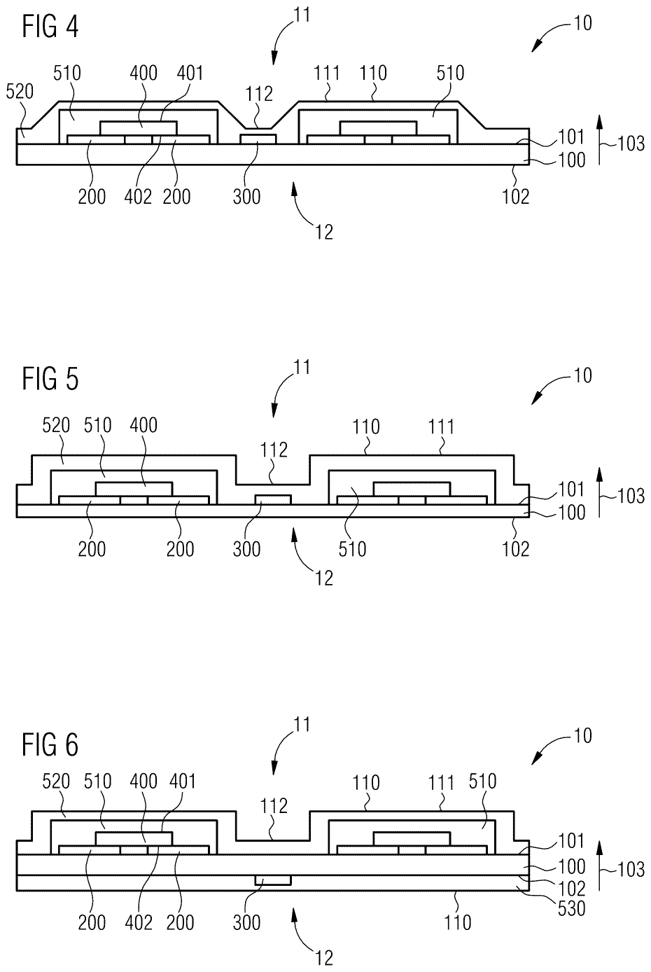

Alternative variants of the optoelectronic device 10 are described below with reference to FIGS. 4 to 9. Here the explanation primarily revolves around how these variants differ from that in FIG. 1. For the rest, the above description of the variant of the optoelectronic device 10 as shown in FIG. 1 also applies to the variants in FIGS. 4 to 9.

FIG. 4 shows a variant of the optoelectronic device 10 in which, proceeding from the processing state shown in FIG. 1, the outer surface 110 formed by the second dielectric 520 was altered by processing. The second dielectric 520 was partly removed in lateral portions arranged above the second metallic structures 300 in the perpendicular direction 103. As a result, raised regions 111 and recessed regions 112 were formed on the outer surface 110. In the raised regions 111, the outer surface 110 is at a higher level in the perpendicular direction 103 than in the recessed regions 112. The recessed regions 112 are arranged over the second metallic structures 300 in the perpendicular direction 103.

Consequently, the second dielectric 520 in the case of the variant of the optoelectronic device 10 shown in FIG. 4, in regions above the second metallic structures 300 in the perpendicular direction 103, comprises a smaller thickness than in the case of the variant shown in FIG. 1. As a result, in the case of the variant shown in FIG. 4, the instance of the user 600 touching the outer surface 110 may cause a more distinct change in the capacitance 330 monitored for the purpose of recognizing the touching, whereby the touching is more easily detectable.

The subsequent processing of the outer surface 110 in order to partly remove the second dielectric 520 may have been effected with the aid of a laser beam, for example.

FIG. 5 shows a variant of the optoelectronic device 10 in which the outer surface 110 formed by the second dielectric 520 on the front side 11 of the optoelectronic device 10 likewise comprises raised regions 111 and recessed regions 112. In the case of this variant, however, the raised regions 111 and the recessed regions 112 were not created by subsequent processing of the outer surface 110. Rather, the second dielectric 520 was directly applied such that the outer surface 110 formed by the second dielectric 520 comprises recessed regions 112 over the second metallic structures 300. This may have been done for example by the second dielectric 520 having been applied with the same thickness measured in the perpendicular direction 103 in all lateral portions. In the case of this variant, the second dielectric 520 may have been applied by a printing method or a spraying method, in particular.

In addition to the increased sensitivity of recognizing touching by the user 600, the variants of the optoelectronic device 10 shown in FIGS. 4 and 5 may afford the advantage that the raised regions 111 and recessed regions 112 formed on the outer surface 110 are tangible to the user 600. This may for example make it easier for the user 600 to touch the outer surface 110 of the optoelectronic device 10 in a targeted manner at a desired position.

The variants of the optoelectronic device 10 shown in FIGS. 6, 7 and 8 differ from the variant in FIG. 1 in that the second metallic structures 300 provided for detecting an instance of the user 600 touching the optoelectronic device 10 are arranged on the rear side 102 of the carrier 100. It is expedient if nevertheless in the case of the variants in FIGS. 6, 7 and 8, too, the second metallic structures 300 are arranged alongside the first metallic structures 200 and the optoelectronic semiconductor chip 400 in a projection in the perpendicular direction 103. If the optoelectronic device 10 comprises a plurality of optoelectronic semiconductor chips 400, then the second metallic structures 300 are expediently arranged between the optoelectronic semiconductor chips 400 in projection in the perpendicular direction 103.

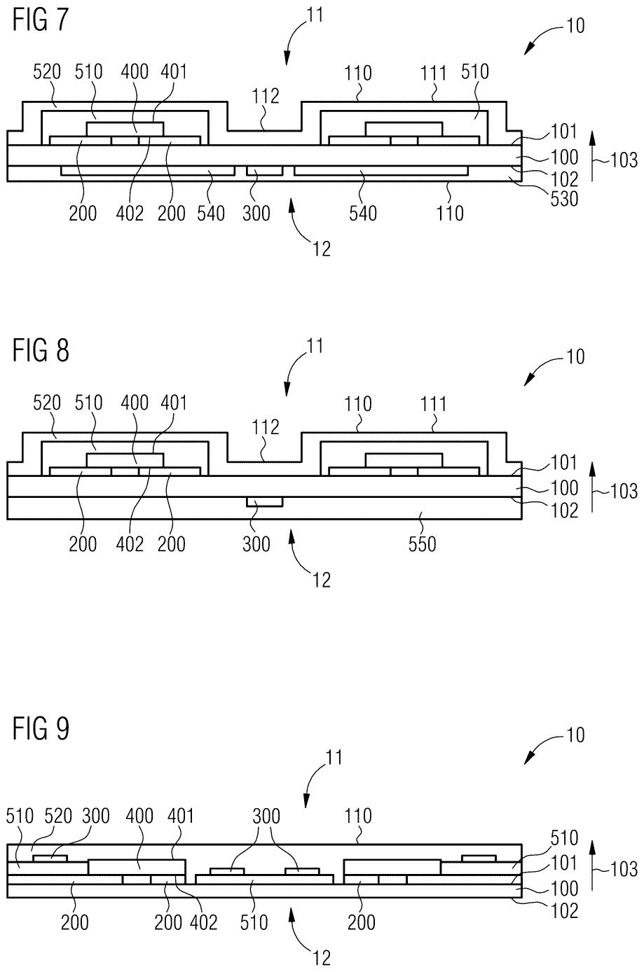

In the case of the variants of the optoelectronic device 10 shown in FIGS. 6 and 7, a third dielectric 530 is arranged on the rear side 102 of the carrier 100. The second metallic structures 300 are embedded in the third dielectric 530 and thereby covered by the third dielectric 530.

It is expedient if the third dielectric 530 comprises a high permittivity, for example a permittivity which is greater than that of SiO₂, for example greater than 3.9. It is expedient if the permittivity of the third dielectric 530 is higher than that of the first dielectric 510. The permittivity of the third dielectric 530 may correspond to the permittivity of the second dielectric 520, for example. The third dielectric 530 and the second dielectric 520 may also comprise the same material. However, it is necessary for the third dielectric 530 to be transparent to light emitted by the optoelectronic semiconductor chip 400 only if emission of light also at the rear side 12 of the optoelectronic device 10 is desired.

In the case of the variants of the optoelectronic device 10 shown in FIGS. 6 and 7, the third dielectric 530 on the rear side 12 of the optoelectronic device 10 may also form an outer surface 110 of the optoelectronic device 10 that is provided for being touched by the user 600. In the case of these variants of the optoelectronic device 10, operation may thus be possible both on the front side 11 and on the rear side 12 of the optoelectronic device 10. Alternatively, only touch-sensitive operation from the rear side 12 may be provided in the case of these variants.

The variant of the optoelectronic device 10 shown in FIG. 7 differs from the variant of the optoelectronic device 10 shown in FIG. 6 in that a fourth dielectric 540 is additionally arranged on the rear side 102 of the carrier 100. The fourth dielectric 540 is arranged in those regions on the rear side 102 of the carrier 100 which lie below the first metallic structures 200 and the optoelectronic semiconductor chips 400 in projection in the perpendicular direction 103. The fourth dielectric 540 is covered by the third dielectric 530. The fourth dielectric 540 expediently comprises a low permittivity, for example a permittivity which is less than that of SiO₂. The third dielectric 530 thus comprises a higher permittivity than the fourth dielectric 540. The fourth dielectric 540 may correspond to the first dielectric 510, for example.

The fourth dielectric 540 comprising a low permittivity that is provided in the variant in FIG. 7 causes a reduction of the disturbing influence—arising from the first metallic structures 200—on the second metallic structures 300 provided for recognizing touching by the user 600.

In the case of the variant of the optoelectronic device 10 shown in FIG. 8, a fifth dielectric 550 is arranged on the rear side 102 of the carrier 100. The second metallic structures 300 are embedded in the fifth dielectric 550 and thereby covered by the fifth dielectric 550. The fifth dielectric 550 comprises a low permittivity, for example a permittivity which is lower than that of SiO₂. The fifth dielectric 550 thus comprises a lower permittivity than the second dielectric 520. The permittivity of the fifth dielectric 550 may correspond to that of the first dielectric 510, for example. The fifth dielectric 550 may comprise the same material as the first dielectric 510.

In the case of the variant of the optoelectronic device 10 shown in FIG. 8, the fifth dielectric 550 particularly effectively reduces disturbing influences on the second metallic structures 300 that arise from the first metallic structures 200.

In the case of the variants of the optoelectronic device 10 shown in FIGS. 6 to 8, the outer surface 110 formed by the second dielectric 520 on the front side 11 of the optoelectronic device 10 is configured in each case with raised regions 111 and recessed regions 112, as is also the case for the variant of the optoelectronic device 10 shown in FIG. 5. However, it is also possible for the outer surface 110 formed by the second dielectric 520 on the front side 11 of the optoelectronic device 10 to be configured as in the case of the variant shown in FIG. 1 or as in the case of the variant shown in FIG. 4.

In the case of the variant of the optoelectronic device 10 shown in FIG. 9, the optoelectronic semiconductor chips 400 are not embedded in the first dielectric 510. Rather, the first dielectric 510 covers the first metallic structures 200 only in portions and comprises cutouts at the positions of the optoelectronic semiconductor chips 400. This makes it possible, during the production of the variant of the optoelectronic device 10 shown in FIG. 9, to mount the optoelectronic semiconductor chips 400 only after the first dielectric 510 has been applied.

In the case of the variant of the optoelectronic device 10 shown in FIG. 9, the optoelectronic semiconductor chips 400 are directly embedded in the second dielectric 520 applied after the optoelectronic semiconductor chips 400 have been arranged. The outer surface 110 formed by the second dielectric 520 on the front side 11 of the optoelectronic device 10, in the case of the variant shown in FIG. 9, is configured as in the case of the variant of the optoelectronic device 10 shown in FIG. 1. However, it is also possible for the outer surface 110 to be configured as in the case of the variant shown in FIG. 4 or as in the case of the variant of the optoelectronic device 10 shown in FIG. 5.

A further special feature of the variant of the optoelectronic device 10 shown in FIG. 9 is that the second metallic structures 300 are arranged at least in portions on the first dielectric 510. For this purpose, the first dielectric 510 was applied before the placement of the second metallic structures 300. The arrangement of the second metallic structures 300 on the first dielectric 510 effectively reduces disturbing influences on the second metallic structures 300 that arise from the first metallic structures 200.

Moreover, crossovers between the first metallic structures 200 and the second metallic structures 300 are made possible by virtue of the second metallic structures 300 being arranged at least in portions on the first dielectric 510. For this purpose, in the region of a crossover, a portion of the first metallic structures 200, a portion of the first dielectric 510 and a portion of the second metallic structures 300 are arranged one above another in the perpendicular direction 103. In this case, the first dielectric 510 comprising a low permittivity ensures that the first metallic structures 200 do not have a strong disturbing influence on the second metallic structures 300.

The invention has been illustrated and described in greater detail on the basis of the preferred exemplary embodiments. However, the invention is not restricted to the examples disclosed.

### LIST OF REFERENCE SIGNS

10 optoelectronic device
11 front side
12 rear side
100 carrier
101 front side
102 rear side
103 perpendicular direction
110 Outer surface
111 raised region
112 recessed region
200 first metallic structures
300 second metallic structures
310 first electrode
320 second electrode
330 capacitance
340 reference potential
400 Optoelectronic semiconductor chip
401 First side
402 second side
510 first dielectric
520 second dielectric
530 third dielectric
540 fourth dielectric
550 fifth dielectric
600 user

1. An optoelectronic device, comprising:
a carrier comprising a front side and a rear side,
wherein first metallic structures are arranged on the front side of the carrier,
wherein an optoelectronic semiconductor chip arranged on the front side of the carrier is electrically contacted via the first metallic structures,
wherein the first metallic structures are at least partly covered by a first dielectric,
wherein a second dielectric forms an outer surface of the optoelectronic device that is provided for being touched by a user,
wherein the second dielectric comprises a higher permittivity than the first dielectric, and
wherein the carrier comprises second metallic structures provided for detecting a change in a capacitance that results from the user touching the optoelectronic device.

2. The optoelectronic device as claimed in claim 1,
wherein the first dielectric is covered by the second dielectric.

3. The optoelectronic device as claimed in claim 1,
wherein the carrier is configured as a film, in particular as a monolayer film.

4. The optoelectronic device as claimed in claim 1,
wherein the second metallic structures are arranged on the front side of the carrier.

5. The optoelectronic device as claimed in claim 4,
wherein the second metallic structures are arranged at least in portions on the first dielectric.

6. The optoelectronic device as claimed in claim 4,
wherein the second metallic structures are embedded directly in the second dielectric.

7. The optoelectronic device as claimed in claim 1,
wherein the second metallic structures are arranged on the rear side of the carrier.

8. The optoelectronic device as claimed in claim 7,
wherein the second metallic structures are covered by a third dielectric, and
wherein the third dielectric comprises a higher permittivity than the first dielectric.

9. The optoelectronic device as claimed in claim 8,
wherein a fourth dielectric is arranged on the rear side of the carrier,
wherein the fourth dielectric is covered by the third dielectric, and
wherein the third dielectric comprises a higher permittivity than the fourth dielectric.

10. The optoelectronic device as claimed in claim 7,
wherein the second metallic structures are covered by a fifth dielectric, and
wherein the fifth dielectric comprises a lower permittivity than the second dielectric.

11. The optoelectronic device as claimed in claim 1,
wherein the outer surface provided for being touched by the user comprises at least one raised region and at least one recessed region, and
wherein the recessed region is arranged over the second metallic structures in a direction perpendicular to the front side of the carrier.

12. The optoelectronic device as claimed in claim 1,
wherein the optoelectronic semiconductor chip is embedded in the first dielectric.

13. The optoelectronic device as claimed in claim 1,
wherein the optoelectronic semiconductor chip is embedded directly in the second dielectric.

14. The optoelectronic device as claimed in claim 1,
wherein the second metallic structures comprise a first electrode, and
wherein the optoelectronic device is configured to detect a change in a capacitance between the first electrode and a reference potential that results from the user touching the device.

15. The optoelectronic device as claimed in claim 1,
wherein the second metallic structures comprise a first electrode and a second electrode, and
wherein the optoelectronic device is configured to detect a change in a capacitance between the first electrode and the second electrode that results from the user touching the device.

16. The optoelectronic device as claimed in claim 1,
wherein the optoelectronic semiconductor chip is configured for emitting light, and
wherein the first dielectric is substantially transparent to the light emitted by the optoelectronic semiconductor chip.

17. The optoelectronic device as claimed in claim 1,
wherein the optoelectronic semiconductor chip is configured for emitting light, and
wherein the second dielectric is substantially transparent to the light emitted by the optoelectronic semiconductor chip.
